(19) United States
(12) Patent Application Publication
(10) Pub. No.: US 2026/0114025 A1
(43) Pub. Date: Apr. 23, 2026

(54) DIODE STRUCTURES OF STACKED TRANSISTORS AND METHODS OF MANUFACTURING THE SAME

(71) Applicant: Samsung Electronics Co., Ltd., Suwon-si (KR)

(72) Inventors: Beomjin Park, Halfmoon, NY (US); Jongmin Shin, Niskayuna, NY (US); Edward Namkyu Cho, Slingerlands, NY (US); Kang-ill Seo, Springfield, VA (US)

(21) Appl. No.: 19/209,197

(22) Filed: May 15, 2025

Related U.S. Application Data
(60) Provisional application No. 63/710,626, filed on Oct. 23, 2024.

(51) Int. Cl. H10D 84/00; H10D 8/00; H10D 8/01; H10D 10/01; H10D 10/40; H10D 10/60; H10D 30/00; H10D 30/01; H10D 62/10; H10D 62/13; H10D 84/01; H10D 88/00

(52) U.S. Cl. CPC H10D 84/121; H10D 8/045; H10D 8/422; H10D 10/051; H10D 10/061; H10D 10/40; H10D 10/60; H10D 30/0191; H10D 30/502; H10D 62/121; H10D 62/151; H10D 84/0109; H10D 88/01

(57) ABSTRACT

A three-dimensional transistor includes a first transistor structure including a first lower source/drain (S/D) region and a first upper S/D region contacting the first lower S/D region at a first junction region, where the first upper S/D region has a first conductivity type, and where the first lower S/D region has a second conductivity type that is opposite to the first conductivity type. The three-dimensional transistor includes a second transistor structure including a second lower S/D region and a second upper S/D region contacting the second lower S/D region at a second junction region, where the second upper S/D region has the first conductivity type, and where the second lower S/D region has the second conductivity type. The three-dimensional transistor includes a first collector/emitter contact electrically connecting the first upper S/D region and the second upper S/D region.

### CLAIM OF PRIORITY

This application claims priority from U.S. Provisional Patent Application No. 63/710,626 entitled “Diode Structures of Stacked Transistors and Methods of Manufacturing the Same,” filed Oct. 23, 2024, with the United States Patent and Trademark Office, the disclosure of which is incorporated by reference herein in its entirety.

### FIELD

The present disclosure relates to circuit devices and methods of forming the same.

### BACKGROUND

Integrated circuit devices may utilize stacked transistors to increase density and improve performance. In some instances, the stacked transistors may be complementary to each other (e.g., complementary metal-oxide-semiconductor (CMOS) transistors). For example, a complementary-FET (CFET) layout may include multiple vertically stacked pairs of gate-all-around field effect transistors (GAAFETs), with P-type GAAFETs on one-level, N-type GAAFETs on another level (i.e., above or below), and shared gates, where each shared gate extends between and wraps around the channel patterns of the stacked pair of N-type and P-type GAAFETs. In such structures, the source/drain regions of the lower GAAFET are electrically isolated from the source/drain regions of the upper GAAFET by dielectric layers. The gates, channel patterns, and isolation structures may be similar in dimensions between the upper and lower devices of the stacked transistors.

### SUMMARY

According to embodiments, a three-dimensional transistor includes a first transistor structure including a first lower source/drain (S/D) region and a first upper S/D region contacting the first lower S/D region at a first junction region, where the first upper S/D region has a first conductivity type, and where the first lower S/D region has a second conductivity type that is opposite to the first conductivity type; a second transistor structure including a second lower S/D region and a second upper S/D region contacting the second lower S/D region at a second junction region, where the second upper S/D region has the first conductivity type, and where the second lower S/D region has the second conductivity type; and a first collector/emitter contact electrically connecting the first upper S/D region and the second upper S/D region.

In some embodiments, the three-dimensional transistor includes a third transistor structure including a third lower S/D region having the second conductivity type contacting the second lower S/D region; and a base contact on the third lower S/D region.

In some embodiments, the third lower S/D region is free of a region of the first conductivity type thereon.

In some embodiments, the three-dimensional transistor includes a fourth transistor structure including a fourth lower S/D region contacting the third lower S/D region and a fourth upper S/D region contacting the fourth lower S/D region at a third junction region, where the fourth upper S/D region has the first conductivity type, and where the fourth lower S/D region has the second conductivity type; a fifth transistor structure including a fifth lower S/D region and a fifth upper S/D region contacting the fifth lower S/D region at a fourth junction region, where the fifth upper S/D region has the first conductivity type, and where the fifth lower S/D region has the second conductivity type; and a second collector/emitter contact electrically connecting the fourth upper S/D region and the fifth upper S/D region.

In some embodiments, the first upper S/D region includes a first upper epitaxial region, and where the second upper S/D region includes a second upper epitaxial region.

In some embodiments, the first lower S/D region includes a first lower epitaxial region, and where the second lower S/D region includes a second lower epitaxial region.

In some embodiments, the first lower S/D region and the second lower S/D region include a unitary epitaxial region.

In some embodiments, the first lower S/D region and the second lower S/D region include a unitary implanted region.

In some embodiments, the three-dimensional transistor includes a third transistor structure including a third lower S/D region and a third upper S/D region contacting the third lower S/D region at a third junction region having a greater junction area than the first or second junction regions, where the third upper S/D region has the first conductivity type, and where the third lower S/D region has the second conductivity type, where the first lower S/D region, the second lower S/D region, and the third lower S/D region include a unitary implanted region.

In some embodiments, the first transistor structure and the second transistor structure are on a first side of a substrate, and a backside contact extends from a second side of the substrate to the first side of the substrate and is electrically connected to the first or second lower S/D region.

According to some embodiments, a three-dimensional transistor includes upper source/drain (S/D) regions having a first conductivity type and including first upper S/D regions and second upper S/D regions; lower S/D regions having a second conductivity type opposite to the first conductivity type and including first lower S/D regions, second lower S/D regions, and a third lower S/D region, where: the first upper S/D regions contact the first lower S/D regions at respective first junction regions, and the second upper S/D regions contact the second the lower S/D regions at respective second junction regions, a first collector/emitter contact is electrically connected to the first upper S/D regions; a second collector/emitter contact is electrically connected to the second upper S/D regions; and a base contact is electrically connected to the third lower S/D region.

In some embodiments, the first upper S/D region includes a first upper epitaxial region, and where the second upper S/D region includes a second upper epitaxial region.

In some embodiments, the first lower S/D region includes a first lower epitaxial region, where the second lower S/D region includes a second lower epitaxial region, and where the third lower S/D region includes a third lower epitaxial region.

In some embodiments, the first lower S/D region, the second lower S/D region, and the third lower S/D region include a unitary epitaxial region.

In some embodiments, the first lower S/D region, the second lower S/D region, and the third lower S/D region include a unitary implanted region.

In some embodiments, the first lower S/D region and the second lower S/D region include a unitary implanted region, the first lower S/D region and the second lower S/D region are on a first side of a substrate, the substrate having a second side that is opposite the first side, and a backside contact extends from the second side of the substrate to the first side of the substrate and is electrically connected to the first lower S/D region or the second lower S/D region.

According to some embodiments, a method of fabricating a three-dimensional transistor includes forming preliminary transistor structures; removing a portion of the preliminary transistor structures to form upper transistor structures that are spaced apart from one another, and one or more lower transistor structure; forming one or more lower source/drain (S/D) regions having a second conductivity type on the one or more lower transistor structure; forming upper S/D regions having a first conductivity type that contact the one or more lower S/D regions at respective junction regions and are on the upper transistor structures; providing an interlayer insulating layer that extends around the upper S/D regions and the one or more lower S/D regions; forming a recess by removing a portion of the interlayer insulating layer between the upper S/D regions; providing a base contact that is in the recess and contacts the one or more lower S/D regions; and providing collector/emitter contacts that are on and contact the upper S/D regions.

In some embodiments, the upper S/D regions are formed by an epitaxial growth process.

In some embodiments, the one or more lower S/D regions are formed by an epitaxial growth process or an implantation process.

In some embodiments, the one or more lower S/D regions include a unitary epitaxial region or a unitary implanted region.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the present disclosure, and be protected by the accompanying claims.

### BRIEF DESCRIPTION OF THE DRAWINGS

FIGS. 1A and 1B are schematic cross-sectional views illustrating various configurations of an example 3D transistor structure according to some embodiments of the present disclosure.

FIG. 1C is an example schematic perspective view illustrating a configuration of an example 3D transistor structure according to some embodiments of the present disclosure.

FIG. 1D is an example schematic cross-sectional view illustrating a configuration of an example 3D transistor structure according to some embodiments of the present disclosure.

FIGS. 2A, 2B, 2C, 2D, and 2E are schematic cross-sectional views illustrating methods of fabricating a 3D transistor structure shown in FIGS. 1A-1D according to some embodiments of the present disclosure.

FIG. 3 is a schematic cross-sectional view illustrating an example configuration of a 3D transistor structure according to some embodiments of the present disclosure.

FIGS. 4A, 4B, 4C, 4D, and 4E are schematic cross-sectional views illustrating methods of fabricating a 3D transistor structure shown in FIG. 3 according to some embodiments of the present disclosure.

FIG. 5 is a schematic cross-sectional view illustrating an example configuration of a 3D transistor structure according to some embodiments of the present disclosure.

FIGS. 6A, 6B, 6C, 6D, and 6E are schematic cross-sectional views illustrating methods of fabricating a 3D transistor structure shown in FIG. 5 according to some embodiments of the present disclosure.

FIG. 7 is a schematic cross-sectional view illustrating an example configuration of a 3D transistor structure according to some embodiments of the present disclosure.

FIG. 8 is a flowchart illustrating a method of fabricating a 3D transistor structure according to some embodiments of the present disclosure.

### DETAILED DESCRIPTION OF EMBODIMENTS

In embodiments described herein, a stacked transistor structure may include a first transistor and a second transistor. The first transistor may be a first type of transistor (e.g., a n-type metal-oxide-semiconductor (NMOS) transistor) and the second transistor may be a second type of transistor (e.g., a p-type metal-oxide-semiconductor (PMOS) transistor). The first and second types of transistors may be complementary to each other (e.g., CMOS transistors), and in some embodiments the stacked transistor structure may be or may include a stack of CMOS transistors. The first and second transistors may be stacked in any order (e.g., with the first transistor on top of the second transistor, or the second transistor on top of the first transistor), resulting in a stack comprising a top device (also referred to herein as an upper device or upper transistor, relative to an underlying substrate) and a bottom device (also referred to herein as a lower device or lower transistor, relative to the underlying substrate). Gates, channels, source/drain regions, and inner spacers of the upper and lower devices may likewise be referred to by the terms “upper” and “lower” (e.g., upper/lower gates, upper/lower channels, upper/lower source/drain regions, and upper/lower inner spacers). Example stacked transistor structures include, but are not limited to, a 3D-stacked field-effect transistor (3DSFET) in a CMOS configuration, a fin transistor, a multibridge-channel field-effect transistor (MBCFET™) in a CMOS configuration, an MBCFET™ that does not include a bulk silicon substrate (e.g., a bulkless MBCFET) and includes bounded shallow trench isolation (STI) regions, a planar transistor, or a field-effect transistor (FET).

Some embodiments of the present disclosure may arise from realization that it may be desirable to improve one or more electrical, performance, and/or operational characteristics of the stacked transistor structure, for example, when implementing backside power delivery networks (BSPDNs). As an example, when implementing BSPDNs with stacked transistor structures (such as 3DSFETs), changes may be desirable in comparison to utilizing bulk silicon. As such, the stacked transistor structures may be subject to undesirable amounts of variability, such as process variations (e.g., doping levels, oxide thickness, etc.), mismatches, dopant fluctuations, etc. Also, some stacked transistor structures may integrate a diode structure in which the top and bottom epitaxial structures/layers (EPIs) have opposite polarities (i.e., opposite conductivity types) and contact each other to define respective junction regions, but may benefit from an enlarged junction area to reduce variability and improve performance.

Embodiments of the present disclosure provide three-dimensional (3D) transistor structures, which may refer to a device that has (or substantially has) the stacked transistor structure but may or may not operate as a transistor. As an example, the 3D transistor structures described herein may incorporate a diode structure and/or bipolar junction transistor structure, and the 3D transistor structures may include relatively larger (or enlarged) junction areas to thereby reduce variability and improve one or more electrical, performance, and/or operational characteristics of the 3D transistor structure. The enlarged junction areas may be provided by removing an interlayer insulating layer at an upper portion of the diode structures, and the 3D transistor structure may utilize the gate-to-gate space skew to improve the channel properties (such as short channel effects) and the diode structure properties.

As an example, the 3D transistor structure may include first and second transistor structures that each include upper and lower source/drain (S/D) regions that contact (e.g., directly contact) each other at first and second junction regions, respectively, and have opposite conductivity types (e.g., p-type and n-type conductivity). The first and second junction regions may collectively form the enlarged junction region (e.g., having a junction area that is the sum of the first and second junction areas). A collector (or emitter) contact may electrically connect the first and second upper S/D regions to thereby form a first diode structure defining a collector region (or an emitter region) with the enlarged junction area. The 3D transistor structure may include additional transistor structures and an emitter (or collector) contact that are configured in a similar manner as the first diode structure to form a second diode structure defining an emitter region (or a collector region). The 3D transistor structure may include a lower S/D region between or otherwise electrically connected to the lower S/D regions of the first and second diode structures and a base contact thereon to therefore provide a 3D transistor structure that functions as a bipolar junction transistor. By providing enlarged junction regions that are respectively formed by selectively removing a portion of an interlayer insulating layer at multiple upper S/D regions of the 3D transistor structure, variability may be reduced or inhibited, and one or more electrical, performance, and/or operational characteristics of the 3D transistor structure (e.g., reduced variation in base-emitter voltages, which may be desirable for a 3D transistor structure that is employed as, for example, a temperature sensor).

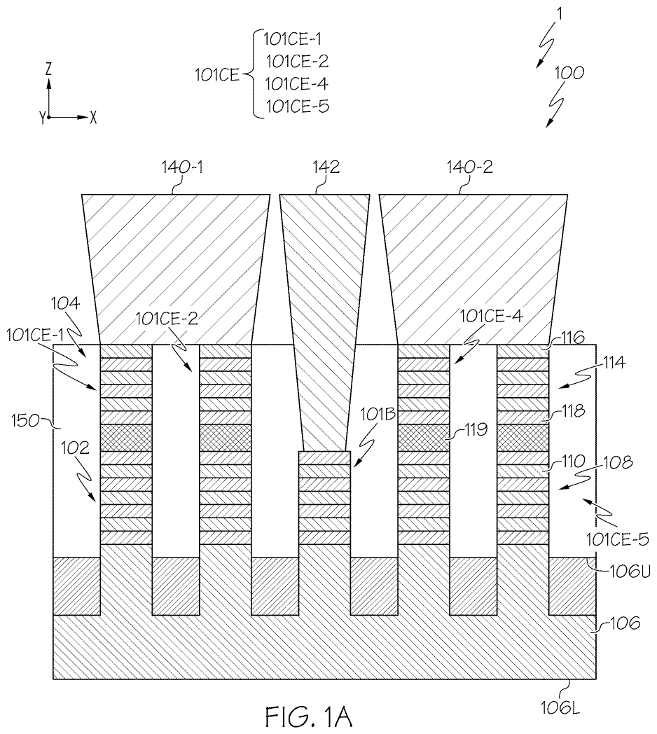

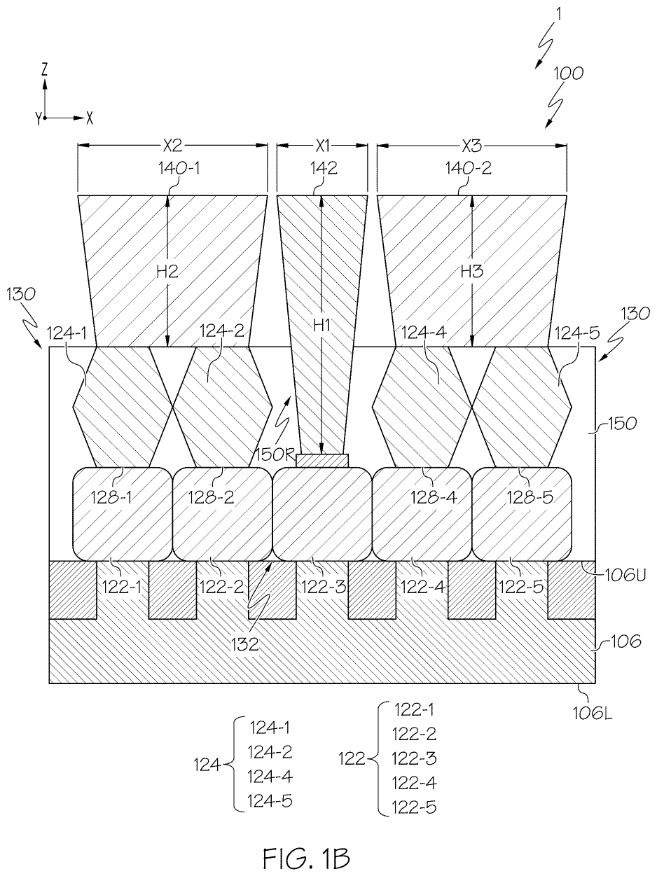

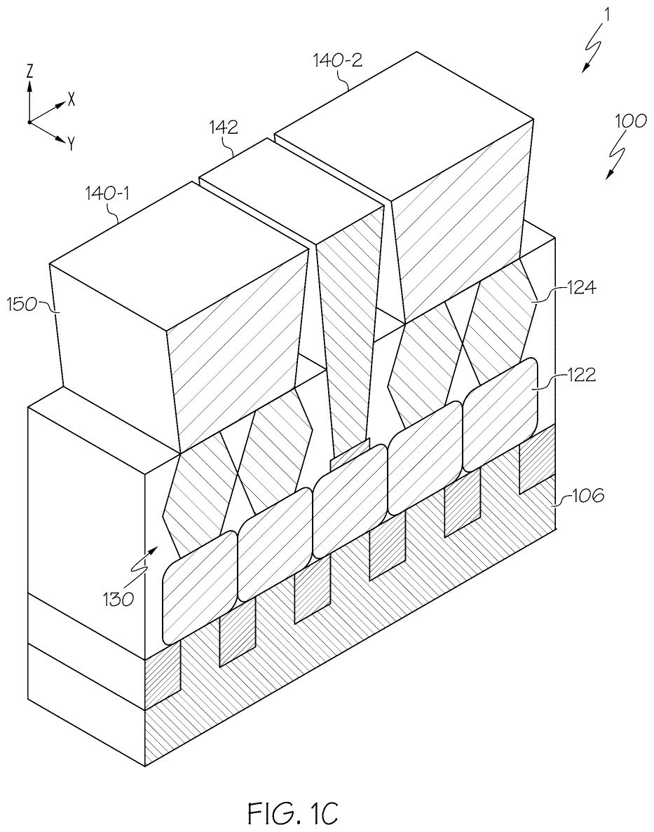

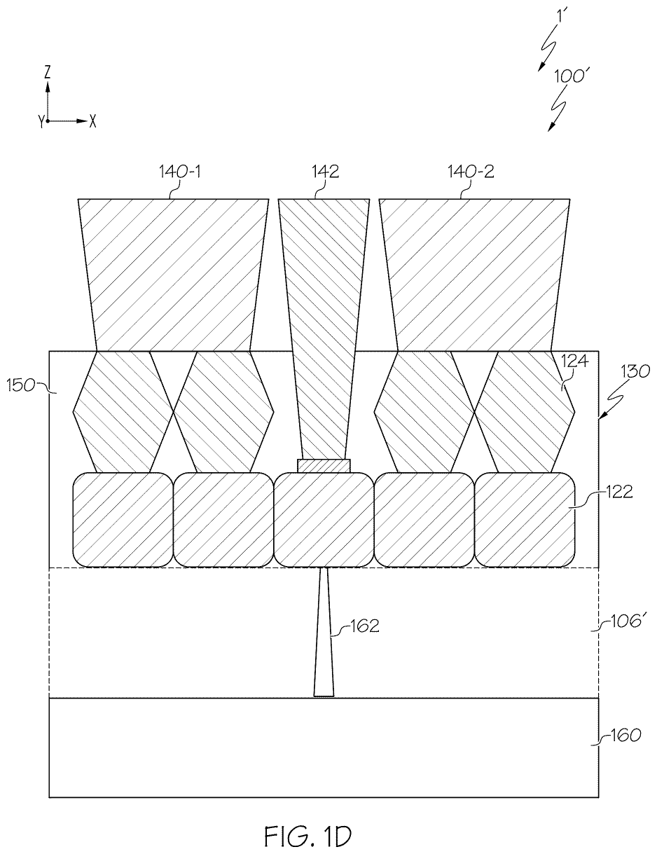

Referring to FIGS. 1A-1C, an integrated circuit device 1 including a 3D transistor structure 100 according to some embodiments of the present disclosure is shown. FIG. 1A is an example cross-sectional view of the integrated circuit device 1 with the diode structures of the 3D transistor structure 100 omitted for clarity, and FIGS. 1B-1C are similar to FIG. 1A but illustrate the diode structures of the 3D transistor structure 100. FIG. 1D is another example cross-sectional view of integrated circuit device 1′, which is similar to the integrated circuit device 1, but includes a bulkless or insulating substrate 106′ and a BSPDN structure 160.

In some embodiments, the 3D transistor structure 100 may have collector/emitter (C/E) transistor structures 101CE including lower and upper regions 102, 104 that are vertically (e.g., in the Z-axis direction) stacked on a substrate 106 and a base transistor structure 101B including the lower region 102 but not including the upper region 104.

In some embodiments, the substrate 106 may include a semiconductor material, such as a group IV semiconductor, a group III-V compound semiconductor, or a group II-VI compound semiconductor. For example, the group IV semiconductor may include silicon, germanium, or silicon-germanium. The substrate 106 may be provided as a bulk wafer, an epitaxial layer, a semiconductor on insulator (SeOI) layer, a silicon on insulator (SOI) layer, a bulkless substrate (e.g., the substrate 106′ of 3D transistor structure 100′ of FIG. 1D), or the like. In some embodiments, the substrate 106′ may include or may be formed of insulating material(s), for example, silicon oxide, silicon oxynitride, silicon nitride, silicon carbonitride, silicon boron nitride and/or a low-k dielectric material.

In some embodiments, the lower regions 102 may have a first conductivity type (e.g., n-type), while the upper regions 104 may have a second conductivity type (e.g., p-type) that is opposite to the first conductivity type, or vice versa. In some embodiments, the lower regions 102 and the upper regions 104 may not define functional CMOS transistors due to the direct contact therebetween. Also, while illustrated with reference to lower and upper regions 102 and 104, it will be understood that 3D transistor structures according to embodiments of the present disclosure are not limited to a two-transistor arrangement, and may include additional transistors (e.g., third transistors, fourth transistors, etc.) that are vertically stacked on the substrate 106.

The lower region 102 may include a lower channel stack 108 comprising a plurality of lower channel patterns 110, and the upper region 104 may include an upper channel stack 114 comprising a plurality of upper channel patterns 116. The lower and upper channel patterns 110, 116 may be similar to channel structures of a 3DSFET (and may be formed by similar processes) and may include various types of semiconductor materials, such as silicon, germanium, gallium arsenide, and/or other known semiconductor materials. In the example of FIGS. 1A-1D, multiple upper channel patterns 116 are vertically stacked (e.g., in the Z-axis direction, which is perpendicular to the upper surface 106U of the substrate 106) on multiple lower channel patterns 110, but embodiments of the present disclosure may include fewer or more channel patterns than shown. Each of the upper channel patterns 116 may have a width in the X-axis direction that is less than a width of each of the lower channel patterns 110 in the X-axis direction. In some embodiments, the widths of the upper channel patterns 116 in the X-axis direction may be the same or different from each other, and the widths of the lower channel patterns 110 in the X-axis direction may be the same or different from each other.

The lower and upper regions 102, 104 may include a gate electrode 118 (i.e., a metal gate) having one or more electrically conductive patterns extending around the lower and upper channel stacks 108, 114 and in the Y-axis direction, which is parallel to the upper surface 106U of the substrate 106. In some embodiments, the gate electrode 118 may include various types of electrically conductive materials, such as doped polycrystalline silicon (Poly-Si), titanium nitride (TiN), tantalum nitride (TaN), molybdenum (Mo), cobalt, (Co), nickel silicide (NiSi), and/or other known electrically conductive materials.

Although not shown, the lower and upper regions 102, 104 may further include inner spacers that are between adjacent ones of the upper and/or lower channel patterns 108, 116, and additional semiconductor (e.g., Si) and insulator (e.g., SiN, SiO) layers stacked on the channel patterns. The inner spacers may include at least one of silicon dioxide or a dielectric material having a dielectric constant greater than silicon dioxide (e.g., hafnium dioxide, aluminum oxide, titanium dioxide, tantalum pentoxide, zirconium dioxide, barium strontium titanate, among other dielectric materials having a greater dielectric constant than silicon dioxide). In some embodiments, the 3D transistor structure 100 may include a middle dielectric isolation layer 119 that includes insulating (e.g., oxidized) materials and may be provided between the lower channel patterns 110 and the upper channel patterns 116. That is, the 3D transistor structure 100 may be structurally similar to (and fabricated using similar processes as) 3DSFET devices that may be provided on other regions of the substrate.

Referring to FIGS. 1B-1C, each of the lower regions 102 of the C/E transistor structures 101CE may include lower source/drain (S/D) regions 122 having a first conductivity type (e.g., n-type). Each of the upper regions 104 of the C/E transistor structures 101CE may include upper S/D regions 124 having a second conductivity type that is opposite to the first conductivity type (e.g., p-type). In some embodiments, the lower S/D regions 122 may include a same material or material composition as the lower channel patterns 110 and the substrate 106. For example, the lower channel patterns 110 and the lower S/D regions 122 may be implemented as silicon layers. In some embodiments, the upper S/D regions 124 may include a different material or material composition than the lower S/D regions 122. For example, the S/D regions 124 may be implemented as silicon germanium (SiGe) layers.

In some embodiments, the lower S/D regions 122 of each of the C/E transistor structures 101CE and the base transistor structure 101B may contact (e.g., directly contact) each other. As an example, lower S/D regions 122-1, 122-2, 122-3, 122-4, 122-5 of C/E transistor structure 101CE-1, C/E transistor structure 101CE-2, base transistor structure 101B, C/E transistor structure 101CE-4, and C/E transistor structure 101CE-5, respectively, may directly contact each other.

In some embodiments, the lower S/D regions 122 of each of the C/E transistor structures 101CE may contact (e.g., directly contact) the respective upper S/D region 124 and are free of an insulating material therebetween (unlike a conventional 3DSFET). Accordingly, each of the respective C/E transistor structures 101CE may respectively define a junction region of a diode structure 130 formed by the lower S/D region 122 and the upper S/D region 124. As an example, the C/E transistor structure 101CE-1 may include a first junction region 128-1 between the lower S/D region 122-1 and the upper S/D region 124-1, the C/E transistor structure 101CE-2 may include a second junction region 128-2 between the lower S/D region 122-2 and the upper S/D region 124-2, the C/E transistor structure 101CE-4 may include a fourth junction region 128-4 between the lower S/D region 122-4 and the upper S/D region 124-4, and the C/E transistor structure 101CE-5 may include a fifth junction region 128-5 between the lower S/D region 122-5 and the upper S/D region 124-5.

In some embodiments, the lower S/D regions 122 and upper S/D regions 124 of each of the C/E transistor structures 101CE may form diode structures 130 due to the junction regions 128 therebetween. The diode structures 130 may correspond to C/E regions 132 of the 3D transistor structure 100. In some embodiments, the base transistor structure 101B may correspond to a base region 134 of the 3D transistor structure 100. In some embodiments, the diode structures 130 may be formed based on an epitaxial growth process, an implantation process, or a combination thereof. As an example, and as shown in FIGS. 1A-1D, the lower S/D regions 122 and the upper S/D regions 124 of each of the C/E transistor structures 101CE and the base transistor structure 101B may be epitaxial regions. In one variation, at least one of the lower S/D regions 122 and the upper S/D regions 124 may be an implanted region, as described below in further detail.

C/E contacts 140-1, 140-2 may be respectively provided on and electrically connected to the C/E regions 132, the diode structures 130, and the junction regions 128, and a base region contact 142 may be on and electrically connected to the base region 134/base transistor structure 101B. The C/E contacts 140-1, 140-2 may be collectively referred to hereinafter as “C/E contacts 140.” The C/E contacts 140 and the base region contact 142 may include known electrically conductive materials. While each of the C/E contacts 140 is shown as being on and electrically connected to two upper S/D regions 124 of two adjacent C/E transistor structures 101CE, it should be understood that the C/E contacts 140 may be on and electrically connected to three or more upper S/D regions 124 of two adjacent C/E transistor structures 101CE or one upper S/D region 124 of a given C/E transistor structure 101CE. In some embodiments, a width X1 of the base region contact 142 in the X-axis direction may be less than a width X2, X3 of each of the C/E contacts 140-1, 140-2, respectively in the X-axis direction. An area of the base region contact 142 in the X-axis and Y-axis directions may be less than an area of each of the C/E contacts 140 in the X-axis and Y-axis directions. A height H1 of the base region contact 142 in the Z-axis direction may be greater than a height H2, H3 of each of the C/E contacts 140-1, 140-2, respectively, in the Z-axis direction.

An interlayer insulating layer (IIL) 150 may extend around (e.g., at least partially surround) each of the C/E transistor structures 101CE and the base transistor structure 101B and at least partially expose upper surfaces of the C/E transistor structures 101CE and the base transistor structure 101B. As an example, the IIL 150 may at least partially expose the upper S/D regions 124 of each of the C/E transistor structures 101CE to thereby enable the electrical connection between the C/E contacts 140 and the C/E regions 132, the diode structures 130, and the junction regions 128. Furthermore, the IIL 150 may include a recessed portion 150R that at least partially exposes the lower S/D region 122-3 of the base transistor structure 101B to thereby enable the electrical connection between the base region contact 142 and the base transistor structure 101B. In some embodiments, the IIL 150 may include known insulating materials.

By removing the IIL 150 to at least partially expose the upper surfaces of the C/E transistor structures 101CE, the IIL 150 may facilitate the electrical connection between the C/E contacts 140 and the enlarged junction areas (i.e., each of the junction regions 128) to thereby reduce the variability of the 3D transistor structure 100. Accordingly, reducing the variability of the 3D transistor structure 100, 100′ may result in improved electrical, performance, and/or operational characteristics of the 3D transistor structure 100, 100′, such as a reduced variation in base-emitter voltage.

As show in FIG. 1D, in some embodiments, a BSPDN structure 160 may be on a lower surface 106L (i.e., the backside) of the substrate 106. For example, the substrate 106 shown in FIGS. 1A-1C may be removed, and may be replaced by an insulating substrate 106′. Backside contacts 162 may extend through the insulating substate 106′ to electrically connect the BSPDN structure 160 to one or more of the lower S/D regions 122. The BSPDN structure 160 may include a backside insulator and one or more backside power rails provided in the backside insulator. The backside power rail may be electrically connected to a power source with a predetermined voltage (e.g., a drain voltage (Vdd) and/or a source voltage (Vss)). For example, the BSPDN structure 160 may include a power delivery network. The power delivery network may include a wiring network, which is used to deliver power (e.g., gate voltages and/or source/drain voltages) to the backside power rail. As used herein, the backside power rail may refer to one or more conductive elements included in the BSPDN structure 160. For example, the backside power rail may include a power rail, a conductive via plug, and/or a conductive wire included in the BSPDN structure 160. That is, the BSPDN structure 160 may include one or more conductive layers (e.g., metal layers) stacked in the Z-axis direction that provide backside power delivery to, for example, the lower S/D regions 122. The conductive layers may respectively be included in insulating layers, and conductive via plugs (e.g., metal via plugs) may electrically connect the conductive layers to each other in the Z-axis direction. The conductive layers may include one or more conductive wires (e.g., metal wires). In some embodiments, an intervening structure (not shown) may be provided between and separate the substrate 106 and the BSPDN structure 160. The BSPDN structure 160 may increase a power delivery efficiency in the integrated circuit device 1, reduce an area used for power delivery in the integrated circuit device 1, and/or improve a voltage drop (i.e., IR drop) in the integrated circuit device 1.

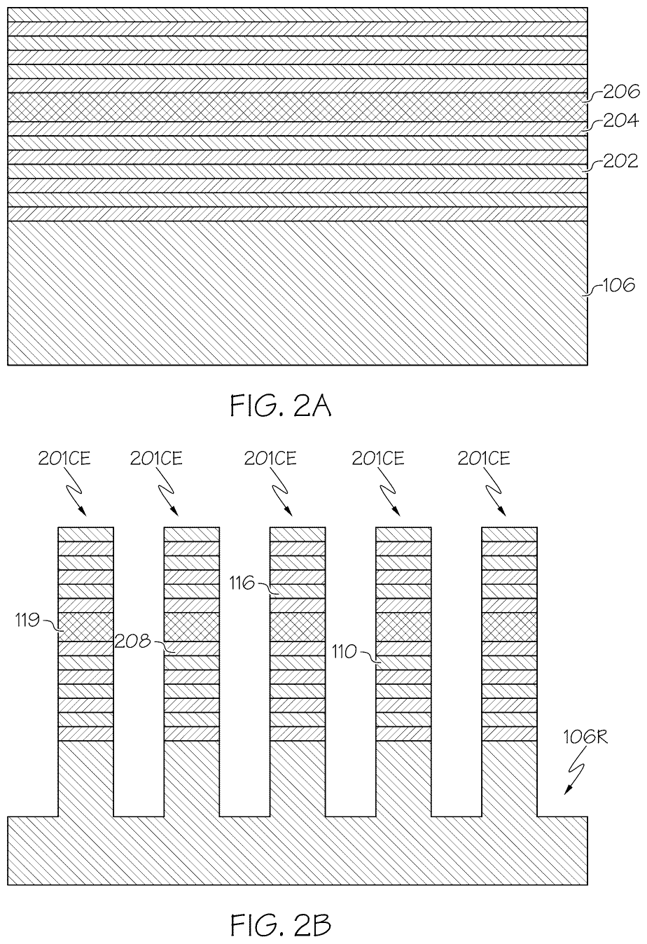

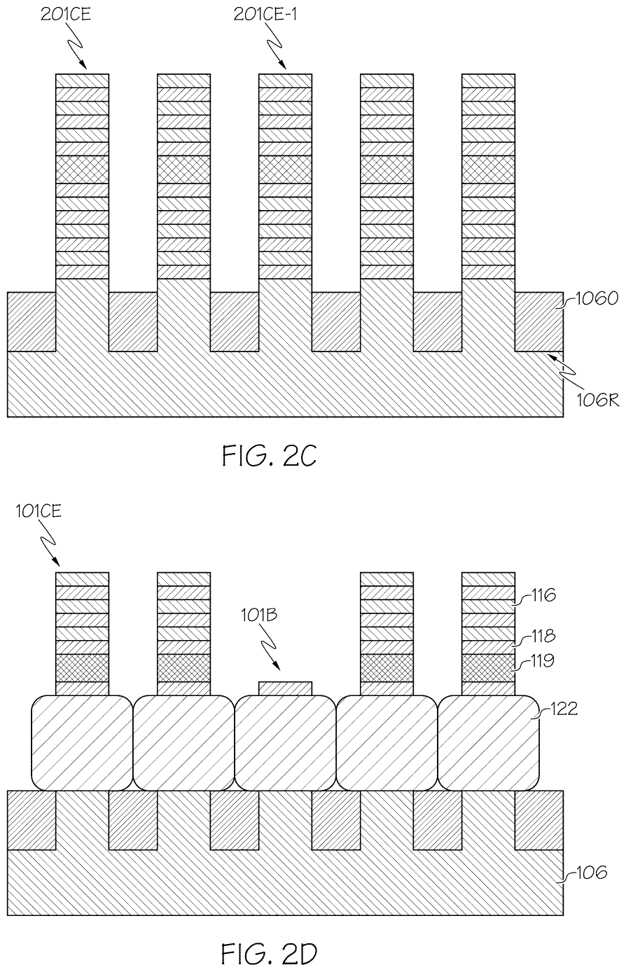

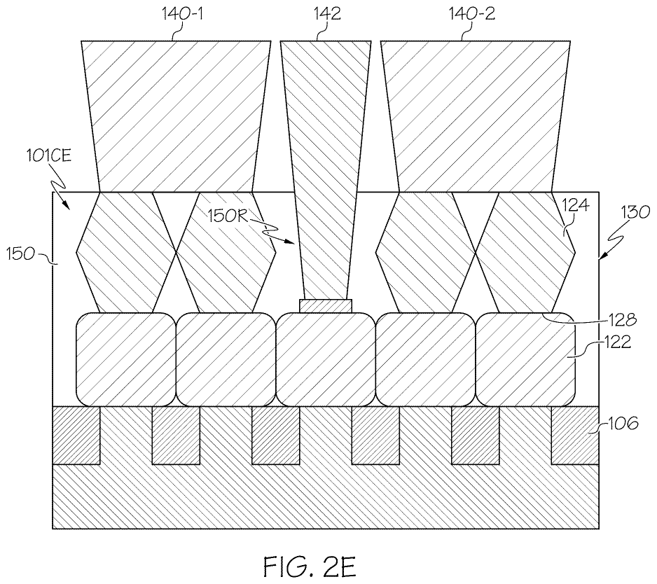

A method of forming 3D transistor structures 100, 100′ is described below with reference to FIGS. 2A-2E, which illustrate schematic cross-sectional views depicting intermediate processes of forming the 3D transistor structures 100, 100′. It should be understood that certain steps may not be performed in various embodiments, and the order of the steps for forming the 3D transistor structures 100, 100′ are not limited to the examples illustrated and described herein.

Referring to FIG. 2A, the method may include forming a plurality of channel layers 202 and sacrificial layers 204 that are alternatingly stacked on the semiconductor portion 106S of the substrate 106. In some embodiments, the method may further include forming a middle sacrificial layer 206 that is between a set of the sacrificial layers 204 (which may correspond to the lower and upper regions 102 and 104). The middle sacrificial layer 206 may have a greater thickness than the sacrificial layers 204 in some embodiments. The plurality of channel layers 202 may include semiconductor materials, such as silicon (Si), and the sacrificial layers 204, 206 may include materials having etching selectivity with the materials of the channel layers 202, such as silicon germanium (SiGe).

Referring to FIG. 2B, the method may include forming preliminary transistor structures 201CE including the upper channel patterns 116, lower channel patterns 110, and sacrificial gate patterns 208. To form the channel patterns 110, 116, the middle dielectric isolation layer 119, and the sacrificial gate patterns 208, for example, the method may include performing a wet etching process and/or a dry etching process, such as plasma-enhanced etching, and using one or more mask patterns (not shown) to form the desired profile. The etching process may involve gases including, but not limited to, HBr, Cl₂, O₂, SF6, and N₂. In some embodiments, the etching process includes performing a dry etching process and controlling parameters thereof to form the desired profile (e.g., controlling mass flow, pressure, power, ion density, and etchant ratios). In some embodiments, the etching process includes performing a wet etching process and controlling parameters thereof to form the desired widths of each of the channel patterns 110, 116, and the sacrificial gate patterns 208 (e.g., controlling the etchant types).

Referring to FIG. 2C, the method may include depositing insulating portions 106O in recesses 106R of the substrate 106 using, for example, chemical vapor deposition (CVD) or other known deposition techniques.

Referring to FIG. 2D, the method may include forming the C/E transistor structures 101CE and the base transistor structure 101B by etching an upper region of one of the preliminary transistor structures 201CE (e.g., a middle preliminary transistor structure 201CE-1 shown in FIG. 2C) using known wet and/or dry etching processes and using one or more mask patterns (not shown).

With continued reference to FIG. 2D, the method may include forming the gate electrode 118 by removing the sacrificial gate patterns 208 using known etching processes, such as a dry/wet etching process, and one or more etching masks. Subsequently, the gate electrode 118 may be deposited to at least partially fill the spaces defined by the removed sacrificial gate patterns.

With continued reference to FIG. 2D, the method may include forming the lower S/D regions 122. Forming the lower S/D regions 122 may include epitaxially growing multiple lower S/D regions 122 (e.g., five lower S/D regions 122 that respectively correspond to the C/E transistor structures 101CE and the base transistor structure 101B) such that they respectively extend around the lower channel patterns 110 of each of the C/E transistor structures 101CE and the base transistor structure 101B.

Referring to FIG. 2E, the method may include forming the upper S/D regions 124. Forming the upper S/D regions 124 may include epitaxially growing multiple upper S/D regions 124 (e.g., four upper S/D regions 124 that respectively correspond to the C/E transistor structures 101CE) such that they respectively extend around the upper channel patterns 116 of each of the C/E transistor structures 101CE. Accordingly, the diode structure 130 and the junction regions 128 may be formed due to the contact between the lower S/D regions 122 and the upper S/D regions 124.

With continued reference to FIG. 2E, the method may further include forming the IIL 150 such that it is on the substrate 106, extends around the C/E transistor structures 101CE and the base transistor structure 101B, and is coplanar with an upper surface of the C/E transistor structures 101CE (e.g., by removing the IIL 150 on the top of the structure, thereby at least partially exposing the upper S/D regions 124 thereof). Subsequently, a portion of the IIL 150 and one of the upper S/D regions 124 that at least partially overlap the base region 134 may be removed (e.g., dry and/or wet etched) using one or more masks (not shown) to thereby form the recessed portion 150R and the base transistor structure 101B. With continued reference to FIG. 2E, the method may include forming the C/E contacts 140 on the exposed portions of the upper S/D regions 124 of the C/E transistor structures 101CE and the base region contact 142 on the base transistor structure 101B (via the recessed portion 150R) using known deposition and/or electroplating processes.

Although not shown in FIGS. 2A-2E, it should be understood that the substrate 106 may be at least partially removed and/or replaced with an insulating substrate 106′, and the BSPDN structure 160 may be attached to the lower surface of the substrate 106′ (and optionally, forming the backside contact 162 extending through the substrate 106′) using known attachment methods to form the integrated circuit 1.

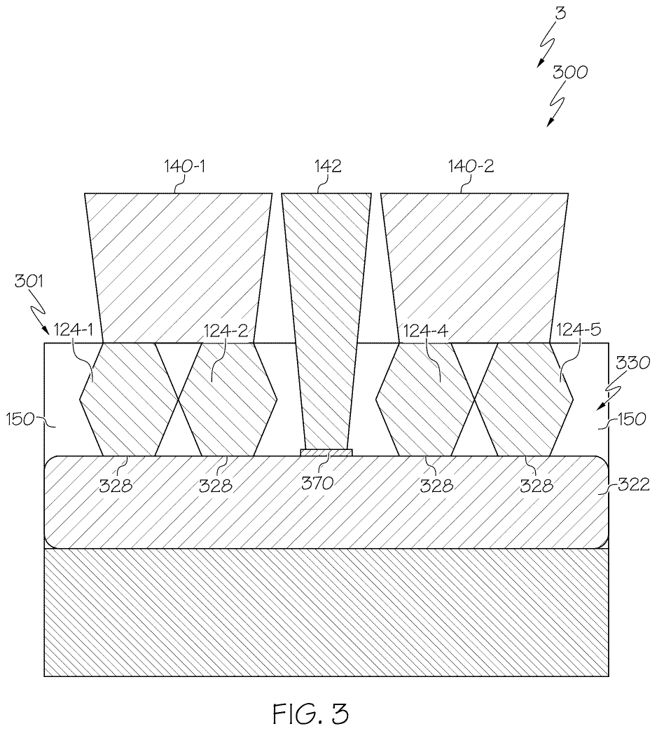

Referring to FIG. 3, a cross-sectional view of an integrated circuit 3 including a 3D transistor structure 300 according to some embodiments of the present disclosure is shown. The 3D transistor structure 300 may be similar to the 3D transistor structures 100, 100′ illustrated in FIGS. 1A-1D, except that the base transistor structure 101B and the C/E transistor structures 101CE are replaced with hybrid transistor structures 301 (e.g., transistor structures having characteristics of FinFETs and bulk transistors). The hybrid transistor structures 301 include a unitary lower S/D region 322 (as opposed to multiple, distinct lower S/D regions 122, as described above) that is in substrate 306, which includes lower channel patterns 110 and portions of the gate electrodes 118 therein as opposed to being above the upper surface 106U of the substrate 106 of FIGS. 1A-1D. In some embodiments, the unitary lower S/D region 322 contacts each of the upper S/D regions 124-1, 124-2, 124-4, 124-5 of the hybrid transistor structures 301 to thereby form diode structures 330 and junction regions 328. In some embodiments, the unitary lower S/D region 322 is an epitaxially grown region or an implanted region, as described below in further detail. A base layer 370 (e.g., a mask layer) may be provided between the unitary lower S/D region 322 and the base region contact 142.

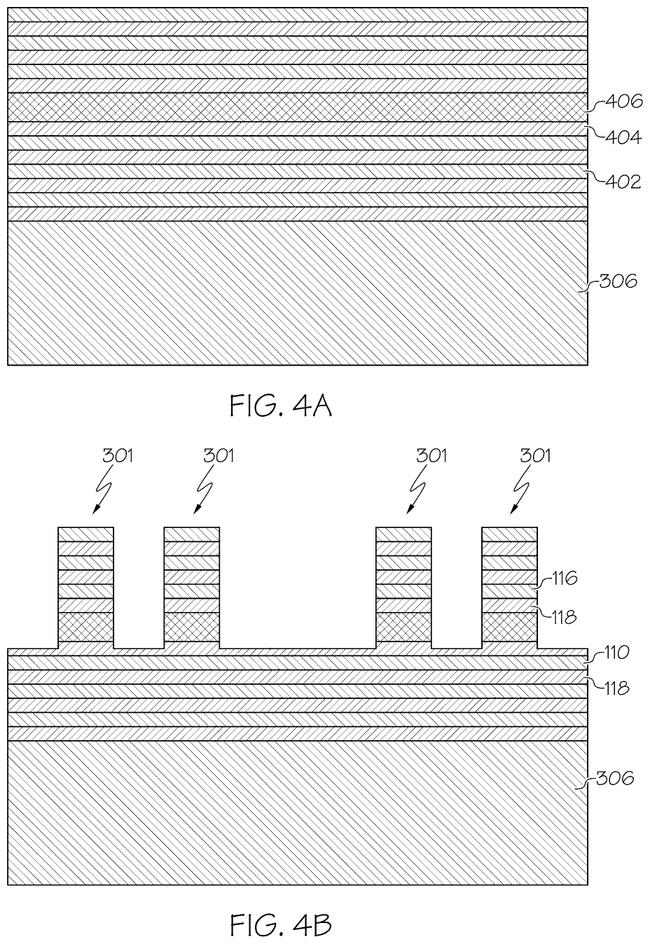

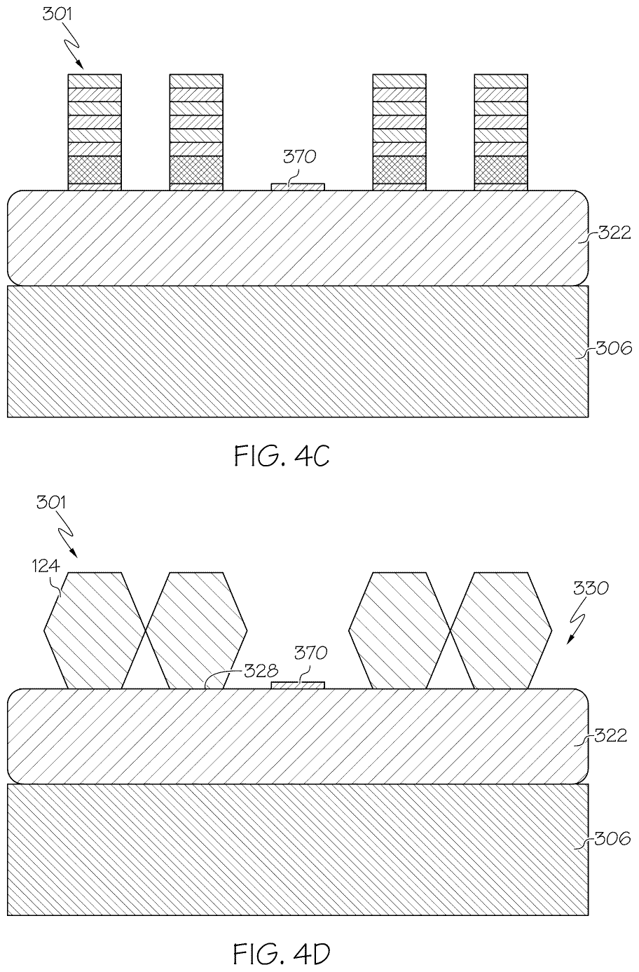

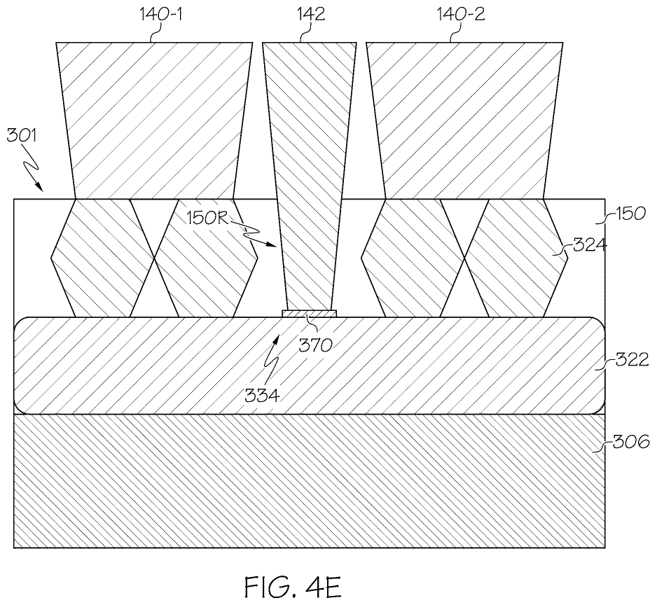

A method of forming the 3D transistor structure 300 is described below with reference to FIGS. 4A-4E, which illustrate schematic cross-sectional views depicting intermediate processes of forming the 3D transistor structure 300. It should be understood that certain steps may not be performed in various embodiments, and the order of the steps for forming the 3D transistor structure 300 are not limited to the examples illustrated and described herein.

Referring to FIG. 4A, the method may include forming a plurality of channel layers 402 and sacrificial layers 404 that are alternatingly stacked on the substrate 306. In some embodiments, the method may further include forming a middle sacrificial layer 406 that is between a set of the sacrificial layers 404. The plurality of channel layers 402 may include semiconductor materials, such as silicon (Si), and the sacrificial layers 404, 406 may include materials having etching selectivity with the materials of the channel layers 402, such as silicon germanium (SiGe).

Referring to FIG. 4B, the method may include forming the lower and upper channel patterns 110, 116 of the hybrid transistor structures 301, which may include performing a wet and/or dry etching processes, such as plasma-enhanced etching, and using one or more mask patterns (not shown). In some embodiments, the etching parameters are selectively modified relative to the etching parameters of FIG. 2B such that the sacrificial layers 404 and the channel layers 402 below the middle sacrificial layer 406 are not etched. With continued reference to FIG. 4B, the method for forming the hybrid transistor structures 301 may further include forming the gate electrode 118 by removing the sacrificial layers 404 using known etching processes, such as a dry/wet etching process, and one or more etching masks. Subsequently, the gate electrode 118 may be deposited to at least partially fill the spaces defined by the removed sacrificial layers 404.

Referring to FIG. 4C, the method may include forming the unitary lower S/D region 322 by epitaxially growing (thereby forming an epitaxial region) or implanting (thereby forming an implanted region) the unitary lower S/D region 322 such that it extends around the lower channel patterns 110 in the substrate 306. With continued reference to FIG. 4C, the method may include forming the base layer 370 on the base region 334.

Referring to FIG. 4D, the method may include forming the upper S/D regions 124. Forming the upper S/D regions 124 may include epitaxially growing multiple upper S/D regions 124 (e.g., four upper S/D regions 124 that respectively correspond to the hybrid transistor structure 301) such that they respectively extend around the upper channel patterns 116 of each of the hybrid transistor structures 301. Accordingly, the diode structure 330 and the junction regions 328 may be formed in response to forming the unitary lower S/D region 322 and the upper S/D regions 124. In some embodiments, one or more masks may be included such that the upper S/D regions 124 are not formed on the base layer 370.

Referring to FIG. 4E, the method may further include forming the IIL 150 such that it is on the substrate 306, extends around the upper S/D regions 124, and is coplanar with an upper surface of the hybrid transistor structures 301 (e.g., by removing at least a portion of the IIL 150 at a top of the structure, thereby at least partially exposing the upper S/D regions 124 thereof). Subsequently, a portion of the IIL 150 and one of the upper S/D regions 124 that at least partially overlap the base region 334 may be removed (e.g., dry and/or wet etched) using one or more masks (not shown) to thereby form the recessed portion 150R. With continued reference to FIG. 4E, the method may include forming the C/E contacts 140 on the exposed portions of the upper S/D regions 124 of the C/E transistor structures 101CE and the base region contact 142 on the base layer 370 and the recessed portion 150R.

Although not shown in FIGS. 4A-4E, it should be understood that the substrate 306 may be at least partially removed and/or replaced with an insulating substrate (e.g., the substrate 106′), and the BSPDN structure 160 may be attached to the lower surface of the substrate (and optionally, forming the backside contact 162 in the substrate) using known attachment methods to form the integrated circuit 3.

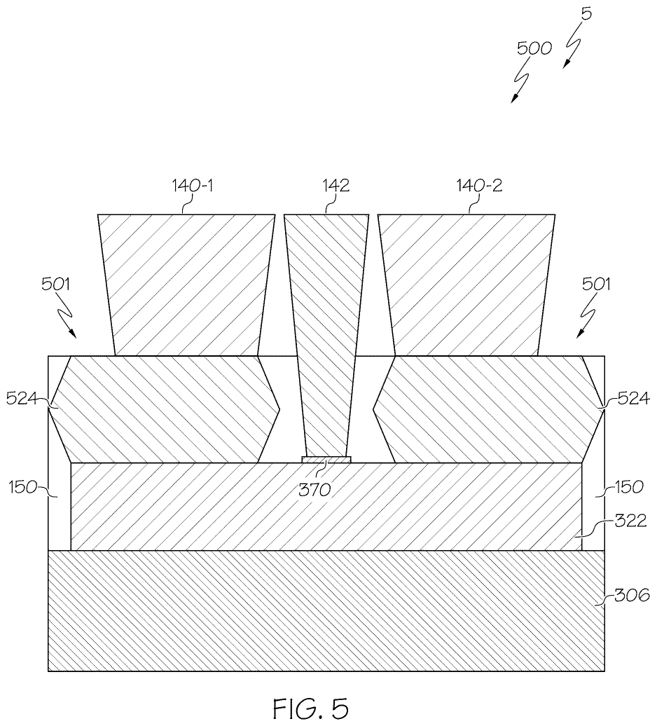

Referring to FIG. 5, a cross-sectional view of an integrated circuit 5 including a 3D transistor structure 500 according to some embodiments of the present disclosure is shown. The 3D transistor structure 500 may be similar to the 3D transistor structure 300 illustrated in FIG. 3, except that the hybrid transistor structures 301 are replaced with bulk transistor structures 501 (e.g., transistor structures having characteristics of bulk transistors) on the substrate 306, and the four upper S/D regions 124 of the hybrid transistor structures 301 are replaced with two upper S/D regions 524 that respectively correspond to the bulk transistor structures 501.

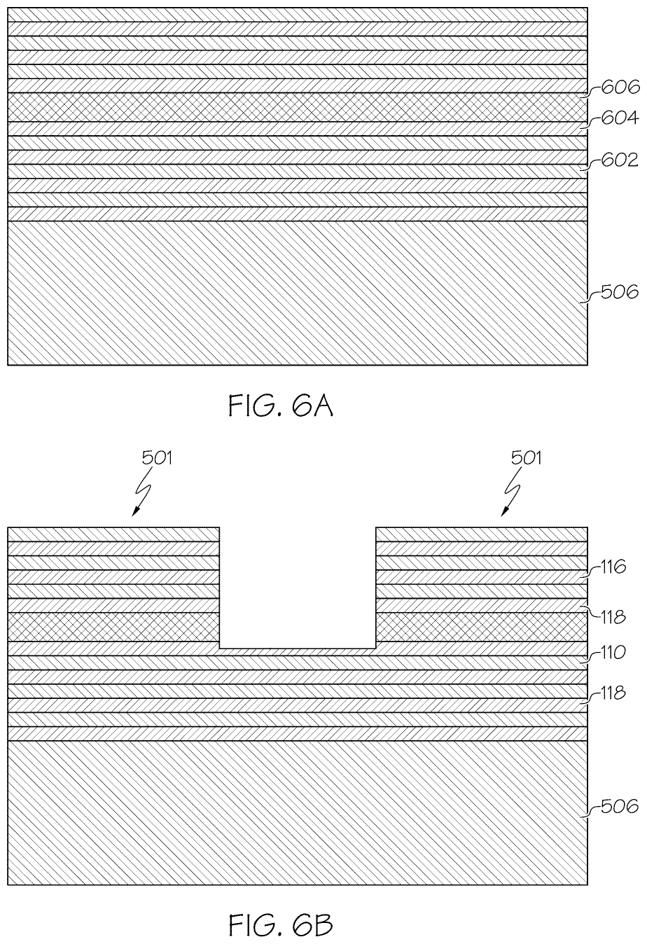

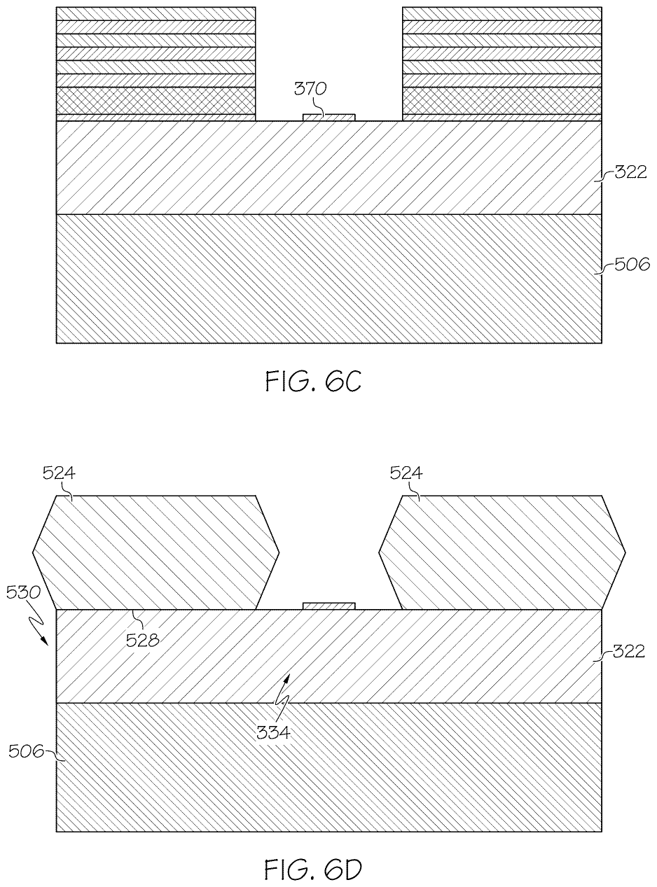

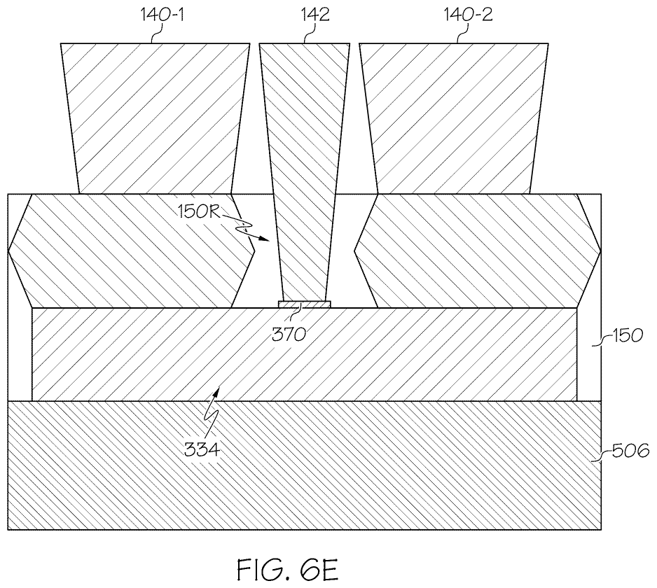

A method of forming 3D transistor structure 500 is described below with reference to FIGS. 6A-6E, which illustrate schematic cross-sectional views depicting intermediate processes of forming the 3D transistor structure 500. It should be understood that certain steps may not be performed in various embodiments, and the order of the steps for forming the 3D transistor structure 500 are not limited to the examples illustrated and described herein.

Referring to FIG. 6A, the method may include forming a plurality of channel layers 602 and sacrificial layers 604 that are alternatingly stacked on the substrate 306. In some embodiments, the method may further include forming a middle sacrificial layer 606 that is between a set of the sacrificial layers 604. The plurality of channel layers 602 may include semiconductor materials, such as silicon (Si), and the sacrificial layers 604, 606 may include materials having etching selectivity with the materials of the channel layers 602, such as silicon germanium (SiGe).

Referring to FIG. 6B, the method may include forming the lower channel patterns 110 and upper channel patterns 116 of the bulk transistor structures 501 including by performing a wet and/or dry etching processes, such as plasma-enhanced etching, and using one or more mask patterns (not shown). With continued reference to FIG. 6B, the method may include forming the gate electrode 118 by removing the sacrificial layers 604 using known etching processes, such as a dry/wet etching process, and one or more etching masks. Subsequently, the gate electrode 118 may be deposited to at least partially fill the spaces defined by the removed sacrificial layers 604.

Referring to FIG. 6C, the method may include forming the unitary lower S/D region 322 by performing an implantation process (and thereby forming an implanted region) such that the unitary lower S/D region 322 extends along lower channel patterns 110 in the substrate 306. With continued reference to FIG. 6C, the method may include forming the base layer 370.

Referring to FIG. 6D, the method may include forming the upper S/D regions 524, which may include epitaxially growing multiple upper S/D regions 524 (e.g., two upper S/D regions 524 that respectively correspond to the bulk transistor structures 501) such that they respectively extend around the upper channel patterns 116. In some embodiments, one or more masks may be included such that the upper S/D regions 524 are not formed on a base region 334 of the 3D transistor structure 500. Accordingly, diode structures 530 and junction regions 528 may be formed in response to forming the unitary lower S/D region 322 and the upper S/D regions 124.

Referring to FIG. 6E, the method may further include forming the IIL 150 such that it is on the substrate 306, extends around the upper S/D regions 524, and is coplanar with an upper surface of bulk transistor structures 501 (e.g., by removing portions of the IIL 150 at the top of the structure, thereby at least partially exposing the upper S/D regions 524 thereof) using known deposition techniques. Subsequently, a portion of the IIL 150 that at least partially overlaps the base region 334 may be removed (e.g., dry and/or wet etched) using one or more masks (not shown) to thereby form the recessed portion 150R. With continued reference to FIG. 6E, the method may include forming the C/E contacts 140 on the exposed portions of the upper S/D regions 524 of the bulk transistor structures 501 and the base region contact 142 on the base layer 370 and the recessed portion 150R.

Although not shown in FIGS. 6A-6E, it should be understood that the substrate 306 may be at least partially removed and/or replaced with an insulating substrate (e.g., substrate 106′), and the BSPDN structure 160 may be attached to the lower surface of the substrate (and optionally, forming the backside contact 162 in the substrate) using known attachment methods to form the integrated circuit 5.

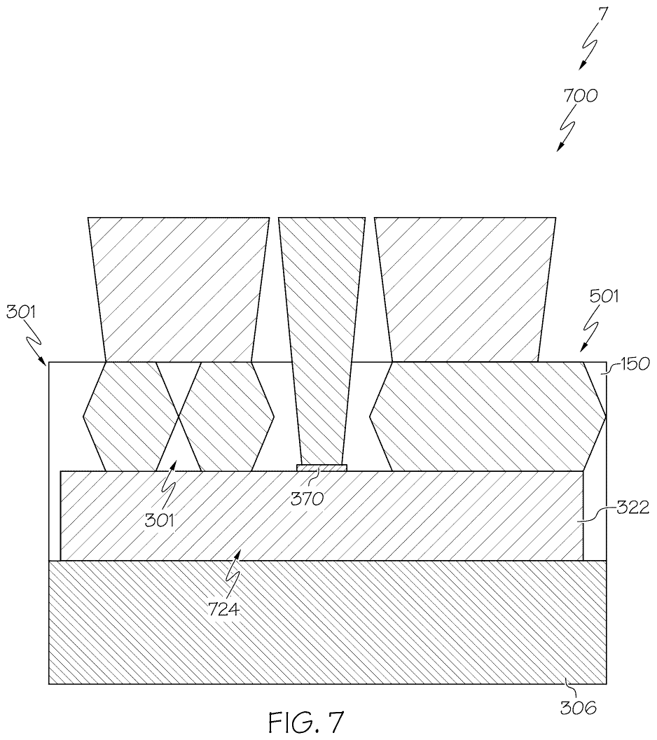

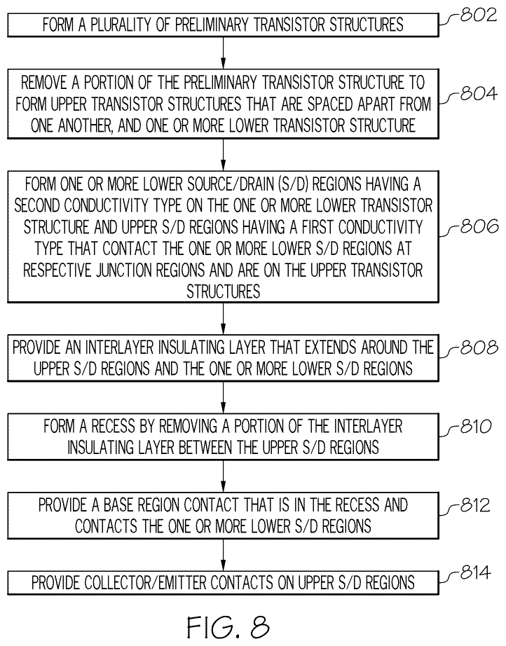

Referring to FIG. 7, a cross-sectional view of an integrated circuit 7 including 3D transistor structure 700 according to some embodiments of the present disclosure is shown. The 3D transistor structure 700 may be similar to the 3D transistor structures 300, 500, as it includes the hybrid transistor structures 301 on a first side of the base region 724 and a bulk transistor structure 501 on a second side of the base region 724. The hybrid transistor structures 301 and the bulk transistor structure 501 may be fabricated based at least in part on the methods described above with reference to FIGS. 4A-4E and 6A-6E.

FIG. 8 is a flowchart 800 illustrating a method of fabricating a 3D transistor according to some embodiments. The method illustrated in flowchart 800 may correspond to intermediate process diagrams described above either alone or in combination, such as the intermediate process diagrams of FIGS. 2A-2E, 4A-4E, and/or 6A-6E. It should be understood that certain steps may not be performed in various embodiments, and the order of the steps for forming the semiconductor device are not limited to the examples illustrated and described herein.

At step 802, the method may include forming a plurality of preliminary transistor structures (e.g., FIGS. 2B, 4B, and 6B). At step 804, the method may include removing a portion of the preliminary transistor structures to form upper transistor structures that are spaced apart from one another (e.g., collector/emitter (C/E) transistor structures 101CE), and one or more lower transistor structure (e.g., the base transistor structure 101B). At step 806, the method may include forming one or more lower source/drain (S/D) regions having a second conductivity type on the one or more lower transistor structure (e.g., FIGS. 2D, 4C, and 6C) and forming upper S/D regions having a first conductivity type that contact the one or more lower S/D regions at respective junction regions and are on the upper transistor structures (e.g., FIGS. 2E, 4D, and 6D). At step 808, the method may include providing an interlayer insulating layer that extends around the plurality of upper S/D regions and the one or more lower S/D regions (e.g., FIGS. 2E, 4E, and 6E), and at step 810, the method may include forming a recess (e.g., the recessed portion 150R) by removing a portion of the interlayer insulating layer between the upper S/D regions. At step 812, the method may include providing a base region contact that is in the recess and contacts the one or more lower S/D regions (e.g., FIGS. 2E, 4E, and 6E). At step 814, the method may include providing C/E contacts that are on and contact the upper S/D regions (e.g., FIGS. 2E, 4E, and 6E).

According to the embodiments of the present disclosure, 3D transistor structures may be provided while incorporating the functionality of a diode structure and/or bipolar junction transistor. Moreover, the 3D transistor structures may include relatively larger (or enlarged) junction areas to thereby improve one or more electrical, performance, and/or operational characteristics of the 3D transistor structure. The enlarged junction areas may be provided by removing an interlayer insulating layer and forming contacts that electrically connect two or more adjacent junction regions at an upper portion of the diode structures and/or by utilizing the gate-to-gate space skew to improve the channel properties and the diode structure properties. However, embodiments of the present disclosure are not limited thereto.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of stated features, steps, operations, elements and/or components, but do not preclude the presence or addition of one or more other features, steps, operations, elements, components and/or groups thereof.

It will be understood that, although the terms “first,” “second,” etc. are used throughout this specification to describe various elements, these elements should not be limited by these terms. These terms are only used to distinguish one element from another. For example, a first element could be termed a second element, and, similarly, a second element could be termed a first element, without departing from the scope of the present disclosure. The term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Spatially relative terms such as “below” or “above” or “upper” or “lower” or “top” or “bottom” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction. As used herein, a “set of object A” may refer to one or more elements of object A (e.g., a set of upper S/D regions may refer to one or more of the upper S/D regions, and a set of lower S/D regions may refer to one or more of the lower S/D regions).

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the disclosure should not be construed as limited to the example embodiments set forth herein. As such, it will be understood by those of ordinary skill in the art that various changes in form and details may be made therein without departing from the spirit and scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the present disclosure are also described with reference to a fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the disclosure. Thus, to the maximum extent allowed by law, the scope is to be determined by the broadest permissible interpretation of the following claims and their equivalents, and shall not be restricted or limited by the foregoing detailed description.

What is claimed is:

1. A three-dimensional transistor, comprising:
a first transistor structure comprising a first lower source/drain (S/D) region and a first upper S/D region contacting the first lower S/D region at a first junction region, wherein the first upper S/D region has a first conductivity type, and wherein the first lower S/D region has a second conductivity type that is opposite to the first conductivity type;
a second transistor structure comprising a second lower S/D region and a second upper S/D region contacting the second lower S/D region at a second junction region, wherein the second upper S/D region has the first conductivity type, and wherein the second lower S/D region has the second conductivity type; and
a first collector/emitter contact electrically connecting the first upper S/D region and the second upper S/D region.

2. The three-dimensional transistor of claim 1, further comprising:
a third transistor structure comprising a third lower S/D region having the second conductivity type contacting the second lower S/D region; and
a base contact on the third lower S/D region.

3. The three-dimensional transistor of claim 2, wherein the third lower S/D region is free of a region of the first conductivity type thereon.

4. The three-dimensional transistor of claim 2, further comprising:
a fourth transistor structure comprising a fourth lower S/D region contacting the third lower S/D region and a fourth upper S/D region contacting the fourth lower S/D region at a third junction region, wherein the fourth upper S/D region has the first conductivity type, and wherein the fourth lower S/D region has the second conductivity type;
a fifth transistor structure comprising a fifth lower S/D region and a fifth upper S/D region contacting the fifth lower S/D region at a fourth junction region, wherein the fifth upper S/D region has the first conductivity type, and wherein the fifth lower S/D region has the second conductivity type; and
a second collector/emitter contact electrically connecting the fourth upper S/D region and the fifth upper S/D region.

5. The three-dimensional transistor of claim 1, wherein the first upper S/D region comprises a first upper epitaxial region, and wherein the second upper S/D region comprises a second upper epitaxial region.

6. The three-dimensional transistor of claim 5, wherein the first lower S/D region comprises a first lower epitaxial region, and wherein the second lower S/D region comprises a second lower epitaxial region.

7. The three-dimensional transistor of claim 6, wherein the first lower S/D region and the second lower S/D region comprise a unitary epitaxial region.

8. The three-dimensional transistor of claim 6, wherein the first lower S/D region and the second lower S/D region comprise a unitary implanted region.

9. The three-dimensional transistor of claim 5, further comprising:
a third transistor structure comprising a third lower S/D region and a third upper S/D region contacting the third lower S/D region at a third junction region having a greater junction area than the first or second junction regions, wherein the third upper S/D region has the first conductivity type, and wherein the third lower S/D region has the second conductivity type,
wherein the first lower S/D region, the second lower S/D region, and the third lower S/D region comprise a unitary implanted region.

10. The three-dimensional transistor of claim 5, wherein:
the first transistor structure and the second transistor structure are on a first side of a substrate, and
a backside contact extends from a second side of the substrate to the first side of the substrate and is electrically connected to the first or second lower S/D region.

11. A three-dimensional transistor, comprising:
upper source/drain (S/D) regions having a first conductivity type and comprising a first upper S/D region and a second upper S/D region;
lower S/D regions having a second conductivity type opposite to the first conductivity type and comprising a first lower S/D region, a second lower S/D region, and a third lower S/D region, wherein:
the first upper S/D region contacts the first lower S/D region at a respective first junction region, and
the second upper S/D region contacts the second the lower S/D region at a respective second junction region,
a first collector/emitter contact electrically connected to the first upper S/D region;
a second collector/emitter contact electrically connected to the second upper S/D region; and
a base contact electrically connected to the third lower S/D region.

12. The three-dimensional transistor of claim 11, wherein the first upper S/D region comprises a first upper epitaxial region, and wherein the second upper S/D region comprises a second upper epitaxial region.

13. The three-dimensional transistor of claim 12, wherein the first lower S/D region comprises a first lower epitaxial region, wherein the second lower S/D region comprises a second lower epitaxial region, and wherein the third lower S/D region comprises a third lower epitaxial region.

14. The three-dimensional transistor of claim 12, wherein the first lower S/D region, the second lower S/D region, and the third lower S/D region comprise a unitary epitaxial region.

15. The three-dimensional transistor of claim 12, wherein the first lower S/D region, the second lower S/D region, and the third lower S/D region comprise a unitary implanted region.

16. The three-dimensional transistor of claim 11, wherein:
the first lower S/D region and the second lower S/D region comprise a unitary implanted region,
the first lower S/D region and the second lower S/D region are on a first side of a substrate, the substrate having a second side that is opposite the first side, and
a backside contact extends from the second side of the substrate to the first side of the substrate and is electrically connected to the first lower S/D region or the second lower S/D region.

17. A method of fabricating a three-dimensional transistor, the method comprising:
forming preliminary transistor structures;
removing a portion of the preliminary transistor structures to form upper transistor structures that are spaced apart from one another, and one or more lower transistor structure;
forming one or more lower source/drain (S/D) regions having a second conductivity type on the one or more lower transistor structure;
forming upper S/D regions having a first conductivity type that contact the one or more lower S/D regions at respective junction regions and are on the upper transistor structures;
providing an interlayer insulating layer that extends around the upper S/D regions and the one or more lower S/D regions;
forming a recess by removing a portion of the interlayer insulating layer between the upper S/D regions;
providing a base contact that is in the recess and contacts the one or more lower S/D regions; and
providing collector/emitter contacts that are on and contact the upper S/D regions.

18. The method of claim 17, wherein the upper S/D regions are formed by an epitaxial growth process.

19. The method of claim 17, wherein the one or more lower S/D regions are formed by an epitaxial growth process or an implantation process.

20. The method of claim 17, wherein the one or more lower S/D regions comprise a unitary epitaxial region or a unitary implanted region.
